(19) United States
(12) Patent Application Publication
(10) Pub. No.: US 2025/0140602 A1
(43) Pub. Date: May 1, 2025

(54) COMPOSITE STRUCTURE AND MANUFACTURING METHOD THEREOF

(71) Applicant: Soitec, BERNIN (FR)

(72) Inventors: Gweltaz Gaudin, BERNIN (FR); Hugo Biard, BERNIN (FR)

(21) Appl. No.: 18/837,681

(22) PCT Filed: Jan. 31, 2023
(86) PCT No.: PCT/EP2023/052346

§ 371 Date: Aug. 12, 2024

(30) Foreign Application Priority Data
Feb. 18, 2022 (FR) 2201443

(51) Int. Cl. H01L 21/762; C30B 29/36

(52) U.S. Cl. CPC H01L 21/76254; C30B 29/36

(57) ABSTRACT

A method of manufacturing a composite structure including a thin layer of a first monocrystalline material arranged on a carrier substrate, the method including: providing an initial substrate of a second polycrystalline material; and depositing, by spin coating, at least on one front surface of the initial substrate, a layer of polymer resin including preformed 3D carbon-carbon bonds; performing a first annealing step at a temperature between 120° C. and 180° C. on the initial substrate provided with the polymer resin layer, to form a layer of cross-linked polymer resin; and performing a second annealing step at a temperature greater than 600° C., in a neutral atmosphere, to convert the layer of cross-linked polymer resin into a glassy carbon film. a composite structure includes a thin layer of a first monocrystalline material on a carrier substrate, which includes a glassy carbon film on an initial substrate of a second polycrystalline.

### CROSS REFERENCE TO RELATED APPLICATIONS

This application is a national phase entry under 35 U.S.C. § 371 of International Patent Application PCT/EP2023/052346, filed Jan. 31, 2023, designating the United States of America and published as International Patent Publication WO 2023/156193 A1 on Aug. 24, 2023, which claims the benefit under Article 8 of the Patent Cooperation Treaty to French Patent Application Serial No. FR2201443, filed Feb. 18, 2022.

### TECHNICAL FIELD

The present disclosure relates to the field of microelectronics and semiconductors. In particular, the present disclosure relates to a substrate made of polycrystalline material comprising a surface film made of glassy carbon, and particularly suitable for receiving a thin layer transferred from a donor substrate. The present disclosure also relates to a process for the manufacture of the support substrate and of the composite structure resulting from the transfer of the thin layer onto the support substrate.

### BACKGROUND

Silicon carbide (SiC) is increasingly widely used for the manufacture of high-performance power devices. Nevertheless, high-quality single-crystal SiC (c-SiC) substrates intended for the microelectronics industry remain expensive and difficult to supply in large sizes. It is thus advantageous to resort to layer transfer solutions in order to produce composite structures typically comprising a thin layer made of c-SiC (resulting from a substrate made of c-SiC of high quality and intended to receive the sensitive functional parts of the devices) on a lower cost support substrate, for example, made of polycrystalline SiC (p-SiC).

One well-known thin-layer transfer solution is the Smart Cut® process, based on an implantation of light ions in a donor substrate (c-SiC) and on an assembling, by direct bonding, at a bonding interface between the donor substrate and a support substrate (for example, made of p-SiC).

Substrates made of p-SiC, as a result of the hardness of the material and of the polycrystalline structure, are difficult to polish and generally exhibit residual service roughnesses that complicate assembling by direct bonding. This is because direct bonding does not call for adhesive substances but involves molecular bonds between the surfaces of the substrates brought into contact: such bonding thus requires excellent flatness and also very low roughness and surface defects.

It is known to deposit an intermediate layer on one and/or other of the substrates to be assembled, the layer being easy to prepare (low roughness, in particular), for the purpose of the assembling by direct bonding. It should be noted that this intermediate layer must not affect the performance qualities of the devices prepared on the composite structure; in this case, for vertical power devices, such an intermediate layer must not affect the vertical electrical conductivity between the thin layer made of c-SiC and the support substrate made of p-SiC.

There is, in particular, known, from the state of the art, the use of intermediate metal layers for ensuring vertical conduction in the composite structure.

Although the present disclosure mentions essentially the advantage of composite structures based on silicon carbide, embodiments of the present disclosure include composite structures based on other materials, which are of high performance but expensive in large-sized substrate and which are complex to prepare for the purpose of thin-layer transfer, as is SiC. Mention may be made, for example, of a composite structure comprising a thin layer made of gallium nitride (GaN) and a polycrystalline support substrate, for example, made of aluminum nitride (AlN).

### BRIEF SUMMARY

The present disclosure provides a solution, alternative to the solutions of the state of the art, which promotes the achievement of a low surface roughness of the support substrate and promotes its electrical and thermal properties. The present disclosure relates, in particular, to a polycrystalline starting substrate comprising a surface film made of glassy carbon, particularly suitable for receiving a working layer transferred from a donor substrate. The present disclosure also relates to a process for the manufacture of the support substrate and of the composite structure resulting from the transfer of the thin layer onto the support substrate.

The present disclosure relates to a process for the manufacture of a composite structure comprising a thin layer made of a first single-crystal material arranged on a support substrate, the manufacturing process comprising the following stages:
a) the provision of a starting substrate made of a second polycrystalline material,
b) the deposition, by centrifugal coating, at least on a front face of the starting substrate, of a polymer resin layer comprising preformed carbon-carbon bonds in three dimensions,
c) the application of a first annealing at a temperature of between 120° C. and 180° C. to the starting substrate provided with the polymer resin layer, in order to form a crosslinked polymer resin layer, and
d) the application of a second annealing at a temperature of greater than 600° C., under a neutral atmosphere, in order to transform the crosslinked polymer resin layer into a glassy carbon film.

According to advantageous characteristics of the present disclosure, taken alone or in any achievable combination:
the process comprises, after stage d), a stage e) of mechanical and/or chemical mechanical polishing of the glassy carbon film;
the polymer resin is based on coal tar, phenol/formaldehyde, polyfurfuryl alcohol, polyvinyl alcohol, polyacrylonitrile, polyvinylidene chloride and/or polystyrene;
the process comprises a stage f) of transfer of a thin layer formed of the first single-crystal material directly onto the glassy carbon film or via an intermediate layer;
stage f) carries out an assembling between a donor substrate comprising the first single-crystal material, from which the thin layer will result, and the glassy carbon film, by direct bonding, to form a bonded assembly;
the donor substrate comprises a weak embedded plane that delimits, with a front face of the substrate, the thin layer to be transferred, and stage f) carries out a separation of the bonded assembly along the weak embedded plane, to give rise, on the one hand, to a composite structure including the thin layer arranged on the glassy carbon film, which structure is itself arranged on the starting substrate, and, on the other hand, the remainder of the donor substrate;
the first single-crystal material is chosen from silicon carbide, gallium nitride, silicon, silicon-germanium, germanium, III-V compounds or other semiconductor materials, or from piezoelectric materials;
the second polycrystalline material is chosen from silicon carbide, aluminum nitride, silicon, silicon-germanium, germanium, III-V compounds or other semiconductor materials, or from piezoelectric materials;
the first material and the second material are semiconductors.

The present disclosure also relates to a composite structure comprising a thin layer made of a first single-crystal material arranged on a support substrate, the support substrate including:
a starting substrate made of a second polycrystalline material, and
a glassy carbon film, in contact with the front surface of the starting substrate.

According to advantageous characteristics of the present disclosure, taken alone or in any achievable combination:
the starting substrate exhibits a surface roughness of between 10 nm and 2 μm peak-to-valley, measured by atomic force microscopy on a surface zone of less than or equal to 30 μm×30 μm;
the glassy carbon film exhibits a thickness of between 100 nm and 4 μm;
the composite structure comprises an intermediate layer, between the thin layer and the glassy carbon film, chosen from silicon, silicon carbide, carbon, tungsten or titanium;
the first single-crystal material is chosen from silicon carbide, gallium nitride or other semiconductor materials, and the second polycrystalline material is chosen from silicon carbide, aluminum nitride or other semiconductor materials.

### BRIEF DESCRIPTION OF THE DRAWINGS

Other characteristics and advantages of the present disclosure will emerge from the detailed description that will follow, with reference to the appended figures, in which:

FIGS. 1A-1D exhibit stages of a process for the manufacture of a support substrate in accordance with the present disclosure;

FIG. 2 exhibits an example of the surface state of a starting substrate composing a support substrate in accordance with the present disclosure;

FIG. 3 exhibits an example of the surface state of a glassy carbon film composing a support substrate in accordance with the present disclosure;

FIGS. 4A-4D exhibit stages of the process for the manufacture of a composite structure in accordance with the present disclosure.

Some figures are diagrammatic representations that, for the purpose of legibility, are not to scale. In particular, the thicknesses of the layers along the z axis are not to scale, with respect to the lateral dimensions along the x and y axes.

In the figures or in the description, the same references may be used for elements of the same nature.

### DETAILED DESCRIPTION

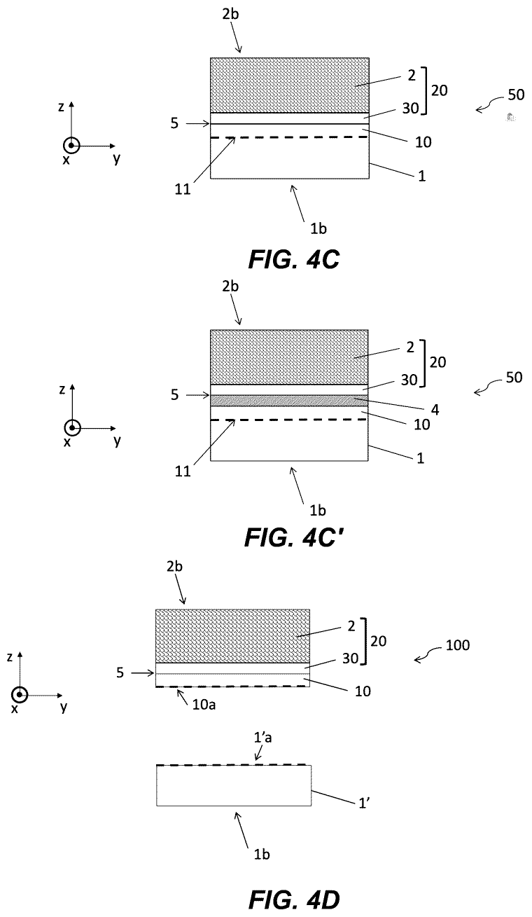

The present disclosure relates to a process for the manufacture of a composite structure 100 comprising a thin layer 10 made of a first single-crystal material arranged on a support substrate 20, which is at least partially composed of a second polycrystalline material (FIG. 4D). The targeted composite structure 100 allows vertical electrical conduction between the thin layer 10 and the support substrate 20, in particular, for power electronic applications.

In particular, the first single-crystal material can be chosen from silicon carbide (c-SiC), gallium nitride (c-GaN), silicon, silicon-germanium, germanium, III-V compounds or other semiconductor materials, or also piezoelectric materials, such as lithium tantalate, lithium niobate, and the like. The second polycrystalline material can be chosen from silicon carbide (p-SiC), aluminum nitride (p-AlN), silicon (p-Si) or any other material stated above with reference to the first material but exhibiting a polycrystalline structure or comprising a surface polycrystalline layer. In the composite structure 100, the first materials stated can be combined with one or other of the above second materials, provided, of course, that this is advantageous for the final application. Advantageously, the composite structure 100 will be formed of a first and of a second material exhibiting similar thermal expansion coefficients.

In the continuation of the description, the case of a first material made of c-SiC and of a second material made of p-SiC will be described. This description nevertheless applies to any other first and second material pair. When certain situations will require it, further information will be given for the different natures of the first and second materials.

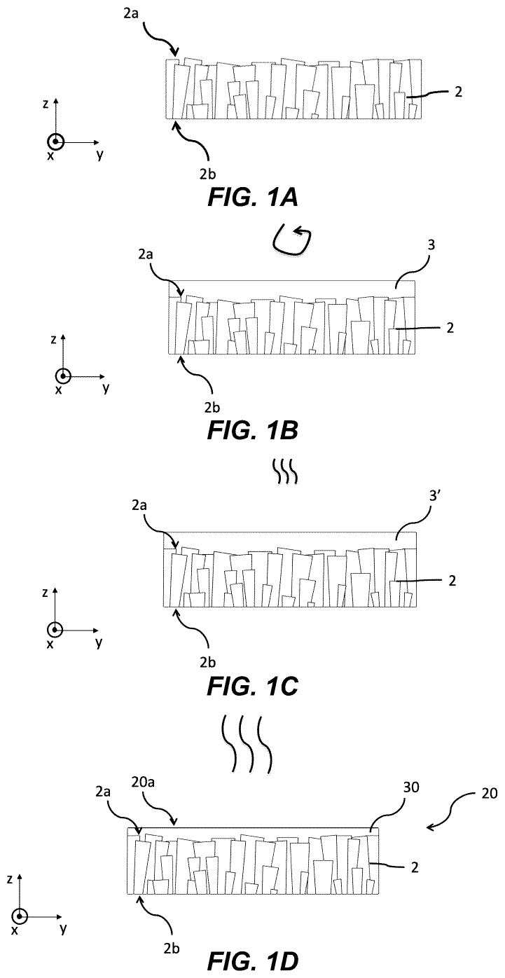

The manufacturing process first comprises a stage a) of providing a starting substrate 2 made of polycrystalline silicon carbide (p-SiC), exhibiting a front face 2a and a back face 2b (FIG. 1A). The starting substrate 2 can be prepared by a conventional technique, such as sintering or chemical vapor deposition.

The starting substrate 2 is preferably in the form of a wafer with a diameter of 100 mm, 150 mm, 200 mm, indeed even 300 mm, and with a thickness typically of between 300 and 800 microns.

The surface state of the front face 2a of the starting substrate 2 is preferably chosen so that the peak-to-valley roughness (subsequently referred to as “PV roughness”) is less than or equal to a few micrometers, typically less than or equal to 2 μm, 1 μm, 500 nm, 100 nm, or also 50 nm.

In the context of the present disclosure, the roughness is measured by atomic force microscopy (AFM) on a surface zone (scan zone) of less than or equal to 30 μm×30 μm. The surface zone measured can, for example, extend over 5 μm×5 μm, 10 μm×10 μm, 20 μm×20 μm or 30 μm×30 μm. Reference will subsequently be made to PV roughness or root mean square or RMS roughness.

It should be remembered that it is complex to obtain a very good surface state on a substrate made of p-SiC, as a result of the hardness of the material and of the polycrystalline structure: mechanical or chemical mechanical polishing can bring about the formation of scratches at the surface of the substrate and the appearance of defects (holes) as a result of the untimely tearing away of p-SiC grains at the surface.

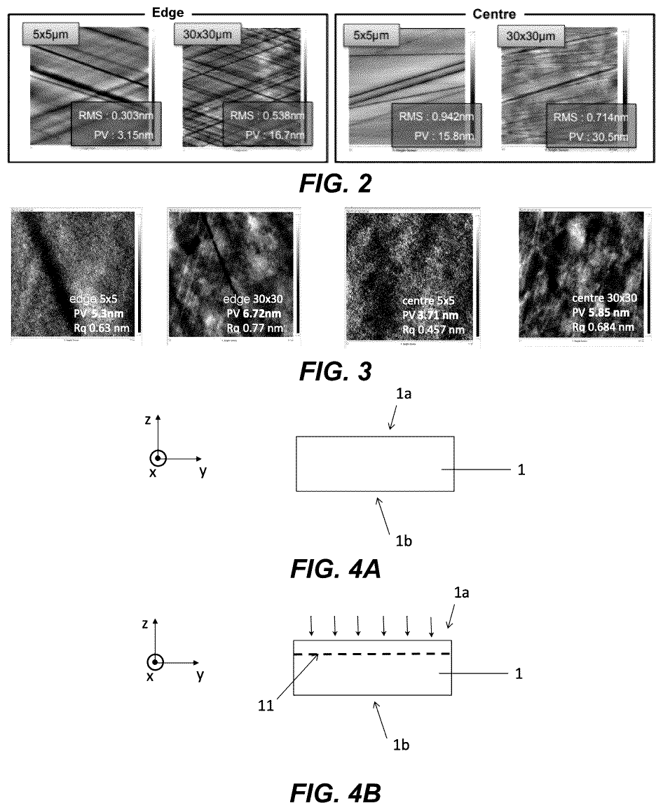

An example of surface state of a starting substrate 2 is given in FIG. 2. Although the RMS roughness remains less than 1 nm, a PV roughness that can exceed 30 nm is observed as a result of the presence of scratches at the surface. Such a surface state is capable of generating physical defects (holes) at the future interface between the substrate and the thin layer of the composite structure 100: this results in degrading the quality and the integrity of the transferred thin layer and also the electrical conductivity of the interface.

Typically, in the context of the present disclosure, the starting substrate 2 can exhibit a PV surface roughness of up to a few micrometers, which greatly relaxes the constraints of manufacturing or supplying the starting substrate 2.

The surface state of the back face 2b of the starting substrate 2 is not specified here. It can be similar to that of the front face 2a or more degraded, provided that it does not affect overall the curvature or the quality (defectivity) of the starting substrate 2.

In order to accommodate the surface state of the starting substrate 2, the manufacturing process according to the present disclosure provides a stage b) comprising a deposition, by centrifugal coating, at least on the front face 2a of the starting substrate 2, of a polymer resin layer 3 (FIG. 1B). An important characteristic of this layer is that it comprises preformed carbon-carbon (C—C) bonds in three dimensions (3D). In this layer, the carbon-based polymer chains, which exhibit sequences of C—C bonds, are dispersed randomly in a solvent: they thus exhibit a more or less random 3D structure. The more randomly these chains are dispersed in 3D, the less graphitization will be promoted and the more a glassy state will be approached, during the crosslinking.

Here a polymer resin layer 3 leading to the highest possible amorphous/crystalline ratio, after crosslinking, will be promoted, in order to obtain a glassy carbon film 30, on conclusion of a subsequent stage d) of the process.

The polymer resin can be formed from coal tar, phenol/formaldehyde, polyfurfuryl alcohol, polyvinyl alcohol, polyacrylonitrile, polyvinylidene chloride and/or polystyrene, and the like.

By way of example, known photosensitive resins, usually employed for photolithography stages in the field of microelectronics, can be used, such as the commercial products:
AZ-5214, AZ-4330, AZ-P4620 (registered trademarks) (based on 1-methoxy-2-propanol acetate, diazonaphthoquinonesulfonic esters, 2-methoxy-1-propanol acetate, cresol novolac resin),
OCG-825 (based on ethyl 3-ethoxypropionate), and
SU-8 2000 (based on cyclopentanone, triarylsulfonium/hexafluoroantimonate salts, propylene carbonate, epoxy resin).

Epoxy resins, such as, for example, the product Epoxy Novolac EPON (registered trademark), provided for covering and protecting various surfaces in varied fields (aeronautical, nautical, automotive, construction, and the like), can also be employed in stage b) of the process according to the present disclosure.

The spreading by centrifugation carried out in stage b) requires that the polymer resin solution be provided in viscous form.

This method of deposition is particularly advantageous because the viscous solution will fill in the hollows (holes and scratches) present at the surface of the starting substrate 2 and thus efficiently planarizes these microreliefs.

The thickness of the polymer resin layer 3 deposited in stage b) can typically vary between a few hundred nanometers (for example, 500 nm) and several microns (for example, 3 to 5 μm).

The manufacturing process subsequently comprises a stage c) consisting of the application of an annealing (the first annealing), exhibiting a stationary phase at a temperature of between 120° C. and 180° C., to the starting substrate 2 provided with the polymer resin layer 3 (FIG. 1C). The stationary phase can have a duration of between a few minutes (typically 30 min) and a few hours (typically 2 h). A gradual rise in temperature, namely between 1° C./min and 5° C./min, from ambient temperature up to the stationary phase is preferred, so as to gradually degas the polymer resin layer 3 and to discharge the solvent and the impurities initially present in the viscous solution.

Intermediate stationary phases can also be provided in the thermal cycle of the first annealing, depending on the nature of the polymer resin.

Subsequent to the first annealing, the polymer resin layer 3′ is crosslinked, thus solidified against the front surface 2a of the starting substrate 2. The crosslinking is characterized by the formation of bonds between the carbon-based chains, which will be reflected by the solidification of the layer 3′. The arrangement, in the crosslinked polymer resin layer 3′, of the polymer chains in 3 dimensions will influence the orientation in 3 dimensions of the chains with bonds of sp² type, during the following stage d) of the process.

Finally, the manufacturing process comprises a stage d) consisting of the application of a second annealing exhibiting a stationary phase at a temperature of greater than 600° C., preferably of greater than 700° C., under a neutral atmosphere, in order to transform the crosslinked polymer resin layer 3′ into a glassy carbon film 30 (FIG. 1D). The stationary phase temperature can, for example, be 650° C., 750° C., 800° C. or also 850° C., or more. The temperature of this stationary phase can range up to approximately 1800° C., care being taken to remain compatible with the nature of the second material composing the starting substrate 2.

This second annealing brings about a carbonization of the crosslinked layer 3′. It is essential for this carbonization to give rise to a glassy carbon structure, which exhibits carbon-carbon (C—C) atomic bonds of sp² type. The structure of glassy carbon can be characterized by Raman spectroscopy, with a specific band (G band) signature, or by ellipsometry, with a specific absorption signature, as is known in the literature.

The glassy carbon film 30 advantageously exhibits 100% of C—C atomic bonds of sp² type; if inclusions of another phase are present in the film 30, it can be tolerated for the percentage of sp² atomic bonds to be greater than 95%, or preferably greater than 99%.

The neutral atmosphere of the second annealing is typically based on argon and/or under vacuum (namely at a pressure below atmospheric and down to a few mbar). The second annealing is carried out with a rise in temperature that can range from 5° C./min, to 15° C./min, and up to 50° C./min, indeed even 100° C./min, from ambient temperature up to the stationary phase. The duration of the stationary phase can vary between a few minutes (for example, 30 min) and a few hours (for example, 2 h).

The glassy carbon film 30 typically exhibits a thickness of between a few hundred nanometers (typically 500-600 nm) and a few micrometers (typically 1, 2, 3 or 4 μm). Preferably, the glassy carbon film 30 exhibits a thickness on the order of 10 times the PV surface roughness of the starting substrate 2.

It is important to take into account the contraction that the viscous polymer resin layer 3 (deposited in stage b) of the process) will undergo during the first annealing (étape c)) and especially during the second annealing (stage d)), in order to define its sufficient starting thickness for the purpose of obtaining the targeted thickness of glassy carbon film 30. The contraction in thickness can typically be between 70% and 95%. The carbon ratio, that is to say the ratio of the weight of the glassy carbon film 30 to the starting weight of the spread polymer resin layer 3, must be at least 5%, preferably greater than 50%.

The starting substrate 2 provided with the glassy carbon film 30 corresponds to the support substrate 20 according to the present disclosure. FIG. 3 exhibits an example of the surface state of the support substrate 20 on the side of its front face 20a, that is a say on the side of the free face of the glassy carbon film 30. A root mean square roughness of less than or equal to 0.8 nm RMS and a peak-to-valley roughness of less than or equal to 7 nm PV can be obtained, starting from the starting substrate 2 roughnesses shown in FIG. 2. The roughnesses are here still measured by atomic force microscopy on a surface zone of less than or equal to 30 μm×30 μm.

The surface state is significantly improved with respect to the front surface 2a of the starting substrate 2; a strong resorption of the scratches and other hollowed defects and a roughness typically of less than or equal to 1 nm RMS and 10 nm PV are observed. This surface state is particularly favorable to an assembling by direct bonding with a very good interface quality.

Advantageously, the manufacturing process according to the present disclosure comprises, after stage d), a stage e) of mechanical and/or chemical mechanical polishing of the glassy carbon film 30, in order to adjust its thickness or in order to further improve its surface roughness.

On conclusion of stage e), an RMS roughness of less than 1 nm, indeed even 0.5 nm, and a PV roughness of less than 5 nm are targeted, for example.

In addition, the glassy carbon film 30 exhibits excellent electrical conduction characteristics, with a resistivity typically of less than 6·10⁻³ ohm·cm.

The mechanical, electrical and thermal properties of the glassy carbon film 30 make the support substrate 20 an excellent candidate for the manufacture of a composite structure 100 by transfer of a thin layer 10 made of single-crystal silicon carbide (c-SiC) onto the support substrate 20.

It should be noted that these mechanical, electrical and thermal properties are also an asset in a composite structure 100, the support substrate 20 of which would comprise, for example, a starting substrate 2 made of p-AlN and the thin layer 10 of which would, for example, be made of c-GaN, or other combinations of first and second materials.

Returning to the description of a composite structure based on SiC, the manufacturing process in accordance with the present disclosure can thus comprise a stage f) of transfer of a thin layer 10 made of c-SiC onto the glassy carbon film 30.

Various options, known from the state of the art, exist for carrying out a thin-layer transfer, which will not be described exhaustively here.

According to a preferred mode, stage f) of the process involves an implantation of light species according to the principle of the Smart Cut® process.

In a first phase f1), a donor substrate 1 made of single-crystal silicon carbide, from which the thin layer 10 will result, is provided (FIG. 4A). The donor substrate 1 is preferably provided in the form of a wafer with a diameter of 100 mm, 150 mm, 200 mm, indeed even 300 mm (identical or very similar to that of the support substrate 20), and with a thickness typically of between 300 μm and 800 μm. It exhibits a front face 1a and a back face 1b. The surface roughness of the front face 1a is advantageously chosen to be less than 1 nm RMS, indeed even less than 0.5 nm RMS, measured by atomic force microscopy (AFM) on a surface zone, for example, of 20 μm×20 μm. The donor substrate 1 can be of polytype 4H or 6H, and exhibit doping of n or p type, depending on the requirements of the components that will be prepared on and/or in the thin layer 10 of the composite structure 100.

It should be noted that the donor substrate 1 intended to form a thin layer 10 made of c-GaN can be formed from a base substrate made of GaN, SiC, Si (111) or sapphire, on which single-crystal GaN epitaxy will be carried out, according to conventional processes.

A second phase f2) corresponds to the introduction of light species into the donor substrate 1 in order to form a weak embedded plane 11 delimiting, with a front face 1a of the donor substrate 1, the thin layer 10 to be transferred (FIG. 4B).

The light species are preferably hydrogen, helium or a co-implantation of these two species, and are implanted at a determined depth in the donor substrate 1, consistent with the targeted thickness of the thin layer 10. These light species will form, around the determined depth, microcavities distributed in a fine layer parallel to the free surface 1a of the donor substrate 1, i.e., parallel to the plane (x,y) in the figures. This fine layer is referred to as the weak embedded plane 11, for the sake of simplicity.

The implantation energy of the light species is chosen so as to reach the determined depth. For example, hydrogen ions will be implanted at an energy of between 10 keV and 250 keV, and at a dose of between 5E16/cm² and 1E17/cm², to delimit a thin layer 10 exhibiting a thickness on the order of 100 nm to 1500 nm. It should be noted that it will be possible to deposit a protective layer on the front face 1a of the donor substrate 1 prior to the ion implantation stage. This protective layer can be composed of a material such as silicon oxide or silicon nitride, for example. It is removed prior to the following phase.

Optionally, an intermediate layer 4 can be formed on the front face 1a of the donor substrate 1, before or after the second phase f2) of introduction of the light species. This intermediate layer 4 can be made of a semiconductor material or of a metal material; for example, it will be possible to choose silicon, silicon carbide, silicon oxycarbide (SiOC), carbon, for example, a glassy or turbostratic carbon, tungsten, titanium, and the like. The thickness of the intermediate layer 4 is advantageously limited, typically to between a few nanometers and a few tens of nanometers.

In the case where the intermediate layer 4 is formed before the phase f2), the implantation energy (and potentially the dose) of the light species will be adjusted to the crossing of this additional layer. In the case where the intermediate layer 4 is formed after the phase f2), care will be taken to form this layer by applying a thermal budget lower than the bubbling thermal budget, the bubbling thermal budget corresponding to the appearance of blisters at the surface of the donor substrate 1 due to excessively great growth and pressurization of the microcavities in the weak embedded plane 11.

The transfer stage f) subsequently comprises a third phase f3) of assembling the donor substrate 1, on the side of its front face 1a, on the support substrate 20, on the side of its first face 20a, by molecular adhesion bonding, along a bonding interface 5, in order to form a bonded assembly 50 (FIGS. 4C. 4C′).

Optionally, an additional layer can also be deposited on the face to be assembled of the support substrate 20 (namely on the glassy carbon film 30), prior to the assembling phase f3); it can be chosen to be of the same nature as or of a different nature from the intermediate layer 4 mentioned for the donor substrate 1. An intermediate layer 4 or additional layer can optionally be deposited only on one or other of the two substrates 1, 20 to be assembled.

The objective of the intermediate layer(s) is essentially to promote the bonding energy (in particular, in the range of temperatures of less than 1100° C.), as a result of the formation of covalent bonds at lower temperatures than in the case of a direct assembling without these intermediate layer(s); another advantage of this (these) intermediate layer(s) can be to further improve the vertical electrical conduction of the bonding interface 5.

Returning to the description of the assembling phase f3) and as is well known per se, the direct bonding by molecular adhesion does not require an adhesive substance because bonds are established at the atomic scale between the assembled surfaces. Several types of bonding by molecular adhesion exist, which differ, in particular, in their conditions of temperature, of pressure, of atmosphere or of treatments prior to bringing the surfaces into contact. Mention may be made of room-temperature bonding, with or without prior plasma activation of the surfaces to be assembled, atomic diffusion bonding (ADB), surface-activated bonding (SAB), and the like.

The assembling phase f3) can comprise, prior to bringing the faces 1a, 20a to be assembled into contact, conventional sequences of chemical cleaning (for example, RCA cleaning), of surface activation (for example, by oxygen or nitrogen plasma) or other surface preparations (such as cleaning by brushing (scrubbing)), which are liable to promote the quality of the bonding interface 5 (low defectivity, high adhesion energy).

Finally, a fourth phase f4) comprises the separation along the weak embedded plane 11, which leads to the thin layer 10 being carried over onto the support substrate 20 (FIG. 4D).

The separation along the weak embedded plane 11 is usually carried out by the application of a heat treatment to the bonded assembly 50 at a temperature of between 800° C. and 1200° C. (in the case described of a bonded assembly 50 based on SiC). Of course, this temperature is strongly dependent on the nature of the first and second materials involved in the bonded assembly 50, as is known to a person skilled in the art, and will naturally be adjusted depending on the materials chosen.

Such a heat treatment induces the development of cavities and microcracks in the weak embedded plane 11 and their pressurization by the light species present in gaseous form, until a fracture propagates along the weak embedded plane 11. Alternatively or jointly, a mechanical stress can be applied to the bonded assembly 50 and, in particular, to the weak embedded plane 11, so as to propagate or assist in propagating mechanically the fracture leading to the separation. On conclusion of this separation, there are obtained, on the one hand, the composite structure 100 comprising the support substrate 20 and the transferred thin single-crystal layer 10 and, on the other hand, the remainder 1′ of the donor substrate. The level and the type of doping of the thin layer 10 are defined by the choice of the properties of the donor substrate 1 or can be adjusted subsequently via the known techniques for the doping of semiconductor layers.

The free surface 10a of the thin layer 10 is usually rough after separation: for example, it exhibits a roughness of between 5 nm and 100 nm RMS (AFM, 20 μm×20 μm scan). Cleaning and/or smoothing phases can be applied in order to restore a good surface state (typically, a roughness of less than a few angstroms RMS, over a 20 μm×20 μm scan by AFM). In particular, these phases can comprise a chemical mechanical smoothing treatment of the free surface of the thin layer 10. A removal of between 50 nm and 300 nm makes it possible to effectively restore the surface state of the layer 10. They can also comprise at least one heat treatment, for example, at a temperature of between 1300° C. and 1800° C. in the case of the composite structure 100 based on SiC.

Such a treatment is applied in order to discharge the residual light species from the thin layer 10 and to promote the rearrangement of its crystal lattice. In addition, it makes it possible to strengthen the bonding interface 5.

The heat treatment can also comprise or correspond to an epitaxy of silicon carbide on the thin layer 10.

The support substrate 20, and, in particular, the glassy carbon film 30, is perfectly compatible with the heat treatments potentially at very high temperatures applied during the preparation of the composite structure 100.

Finally, it should be noted that the transfer stage f) can comprise a stage of reconditioning the remainder 1′ of the donor substrate for the purpose of reuse as donor substrate 1 for a new composite structure 100. Mechanical and/or chemical treatments, similar to those applied to the composite structure 100, can be applied to the front face 1′a of the remaining substrate 1′.

The composite structure 100 obtained comprises a thin layer 10 made of single-crystal silicon carbide arranged on the support substrate 20, the support substrate 20 including a starting substrate 2 made of polycrystalline silicon carbide and a glassy carbon film 30, in contact with the front surface 2a of the starting substrate 2.

As mentioned above with reference to the manufacturing process according to the present disclosure, the composite structure 100 is described here in the case of a first material made of c-SiC and of a second material made of p-SiC. The present disclosure also relates to a composite structure 100 based on other pairs of first and second materials (stated non-exhaustively above), in particular, a composite structure 100 comprising a thin layer made of c-GaN and a starting substrate 2 (included in the support substrate 20) made of p-AlN.

An intermediate layer 4 and/or an additional layer such as were mentioned in the process can optionally be inserted between the glassy carbon film 30 and the thin layer 10. The case of an intermediate layer 4 made of carbon is advantageous in that it does not add an interface of separate material liable to increase the total vertical resistance and provides a very good temperature stability.

The electrical conduction at the interface between the thin layer 10 and the intermediate layer 4 or the glassy carbon film 30 is advantageously less than or equal to 10⁻⁴ ohm·cm², indeed even less than 10⁻⁵ ohm·cm², indeed even less than 10⁻⁶ ohm·cm².

Such a composite structure 100 is extremely robust to the high-temperature heat treatments liable to be applied in order to manufacture components on and/or in the layer 10. The composite structure 100 according to the present disclosure is particularly suitable for the preparation of one (or more) high-voltage microelectronic component(s), such as, for example, Schottky diodes, MOSFET transistors, and the like. More generally, it is suitable for power microelectronic applications, allowing excellent vertical electrical conduction, good thermal conductivity and affording a high-quality working layer made of single-crystal material.

Of course, the present disclosure is not limited to the embodiments described and alternative embodiments can be introduced thereto without departing from the scope of the invention as defined by the claims.

1. A method of manufacturing a composite structure including a thin layer of a first single-crystal material on a support substrate, the method comprising the following stages:
a) providing a starting substrate comprising a second polycrystalline material;
b) depositing, by centrifugal coating, at least on a front face of the starting substrate, a polymer resin layer comprising preformed carbon-carbon bonds in three dimensions;
c) applying a first annealing at a temperature of between 120° C. and 180° C. to the starting substrate provided with the polymer resin layer to form a crosslinked polymer resin layer;
d) applying a second annealing at a temperature of greater than 600° C., under a neutral atmosphere, to transform the crosslinked polymer resin layer into a glassy carbon film; and
f) transferring the thin layer formed from the first single-crystal material directly onto the glassy carbon film or via an intermediate layer, the transfer involving forming an interface of bonding by molecular adhesion, between a face of the glassy carbon film and a face of the thin layer, or between a face of the glassy carbon film and a face of an intermediate layer arranged between the glassy carbon film and the thin layer.

2. The method of claim 1, further comprising, after stage d), a stage e) of mechanical and/or chemical mechanical polishing of the glassy carbon film.

3. The method of claim 2, wherein the polymer resin layer comprises coal tar, phenol/formaldehyde, polyfurfuryl alcohol, polyvinyl alcohol, polyacrylonitrile, polyvinylidene chloride and/or polystyrene.

4. Manufacturing process according to one of the preceding claims The method of claim 3, wherein stage f) further comprises assembling a donor substrate including the first single-crystal material, from which the thin layer will be transferred, and the glassy carbon film, to form a bonded assembly.

5. The method of claim 4, wherein:
the donor substrate comprises a weak embedded plane delimiting, with a front face of the substrate, the thin layer to be transferred; and
stage f) further comprises separating the bonded assembly along the weak embedded plane to form a composite structure including the thin layer on the glassy carbon film and a remainder of the donor substrate.

6. The method of claim 5, wherein the first single-crystal material is chosen from silicon carbide, gallium nitride, silicon, silicon-germanium, germanium, III-V compounds or other semiconductor materials, or from piezoelectric materials.

7. The method of claim 6, wherein the second polycrystalline material is chosen from silicon carbide, aluminum nitride, silicon, silicon-germanium, germanium, III-V compounds or other semiconductor materials, or from piezoelectric materials.

8. The method of claim 1, wherein the first material and the second material are semiconductors.

9. A composite structure, comprising:
a thin layer of a first single-crystal material; and
a support substrate, the support substrate including:
a starting substrate comprising a second polycrystalline material; and
a glassy carbon film in contact with the front surface of the starting substrate; and
wherein the composite structure further comprises an interface of bonding by molecular adhesion, between a face of the glassy carbon film and a face of the thin layer or between a face of the glassy carbon film and a face of an intermediate layer arranged between the glassy carbon film and the thin layer.

10. The composite structure of claim 9, wherein the starting substrate exhibits a surface roughness of between 10 nm and 2 μm peak-to-valley, measured by atomic force microscopy on a surface zone of less than or equal to 30 μm×30 μm.

11. The composite structure of claim 10, wherein the glassy carbon film exhibits a thickness of between 100 nm and 4 μm.

12. The composite structure of claim 11, further comprising an intermediate layer between the thin layer and the glassy carbon film, the intermediate layer comprising a material chosen from silicon, silicon carbide, carbon, tungsten or titanium.

13. The composite structure of claim 12, wherein the first single-crystal material is chosen from silicon carbide, gallium nitride or other semiconductor materials and the second polycrystalline material is chosen from silicon carbide, aluminum nitride or other semiconductor materials.

14. The composite structure of claim 9, wherein the glassy carbon film exhibits a thickness of between 100 nm and 4 μm.

15. The composite structure of claim 14, further comprising an intermediate layer between the thin layer and the glassy carbon film, the intermediate layer comprising a material chosen from silicon, silicon carbide, carbon, tungsten or titanium.

16. The composite structure of claim 9, wherein the first single-crystal material is chosen from silicon carbide, gallium nitride or other semiconductor materials and the second polycrystalline material is chosen from silicon carbide, aluminum nitride or other semiconductor materials.

17. The method of claim 1, wherein stage f) further comprises assembling a donor substrate including the first single-crystal material, from which the thin layer will be transferred, and the glassy carbon film, to form a bonded assembly.

18. The method of claim 17, wherein:
the donor substrate comprises a weak embedded plane delimiting, with a front face of the substrate, the thin layer to be transferred; and
stage f) further comprises separating the bonded assembly along the weak embedded plane to form a composite structure including the thin layer on the glassy carbon film and a remainder of the donor substrate.

19. The method of claim 1, wherein the first single-crystal material is chosen from silicon carbide, gallium nitride, silicon, silicon-germanium, germanium, III-V compounds or other semiconductor materials, or from piezoelectric materials.

20. The method of claim 1, wherein the second polycrystalline material is chosen from silicon carbide, aluminum nitride, silicon, silicon-germanium, germanium, III-V compounds or other semiconductor materials, or from piezoelectric materials.
